(19) United States
(12) Patent Application Publication
(10) Pub. No.: US 2011/0290176 A1
(43) Pub. Date: Dec. 1, 2011

(54) CLUSTER TOOL FOR EPITAXIAL FILM FORMATION

(75) Inventor: Arkadii V. Samoilov, Saratoga, CA (US)

(73) Assignee: Applied Materials, Inc., Santa Clara, CA (US)

(21) Appl. No.: 13/206,088

(22) Filed: Aug. 9, 2011

Related U.S. Application Data
(62) Division of application No. 11/697,523, filed on Apr. 6, 2007.
(60) Provisional application No. 60/790,066, filed on Apr. 7, 2006.

(51) Int. Cl. C30B 25/02

(52) U.S. Cl. 117/97

(57) ABSTRACT

Systems, methods, and apparatus are provided for using a cluster tool to pre-clean a substrate in a first processing chamber utilizing a first gas prior to epitaxial film formation, transfer the substrate from the first processing chamber to a second processing chamber through a transfer chamber under a vacuum, and form an epitaxial layer on the substrate in the second processing chamber without utilizing the first gas. Numerous additional aspects are disclosed.

This application is a division of, and claims priority to, U.S. Non-Provisional patent application Ser. No. 11/697,523, filed Apr. 6, 2007, and titled “CLUSTER TOOL FOR EPITAXIAL FILM FORMATION” (Attorney Docket No. 10318), which claims priority to U.S. Provisional Patent Application Ser. No. 60/790,066, filed Apr. 7, 2006 (Docket No. 10318/L), entitled “Cluster Tool For Epitaxial Film Formation.” Each of the above applications is hereby incorporated by reference herein in its entirety.

### CROSS REFERENCE TO RELATED APPLICATION

This application is related to U.S. patent application Ser. No. 11/047,323, filed Jan. 28, 2005 (Docket No. 9793) and U.S. patent application Ser. No. 11/227,974, filed Sep. 14, 2005 (Docket No. 9618/P1), which is a continuation-in-part of and claims priority to U.S. patent application Ser. No. 11/001,774, filed Dec. 1, 2004 (Docket No. 9618).

### FIELD OF THE INVENTION

The present invention relates generally to semiconductor device manufacturing, and more specifically to a cluster tool for use during epitaxial film formation.

### BACKGROUND

A conventional selective epitaxy process involves a deposition reaction and an etch reaction. The deposition and etch reactions occur concurrently with relatively different reaction rates to an epitaxial layer and to a polycrystalline layer. During the deposition process, the epitaxial layer is formed on a monocrystalline surface while a polycrystalline layer is deposited on at least a second layer, such as an existing polycrystalline layer and/or an amorphous layer. However, the deposited polycrystalline layer is generally etched at a faster rate than the epitaxial layer. Therefore, by changing the concentration of an etchant gas, the net selective process results in deposition of epitaxy material and limited, or no, deposition of polycrystalline material. For example, a selective epitaxy process may result in the formation of an epilayer of silicon-containing material on a monocrystalline silicon surface while no deposition is left on the spacer.

Selective epitaxy processes generally have some drawbacks. In order to maintain selectivity during such epitaxy processes, chemical concentrations of the precursors, as well as reaction temperatures must be regulated and adjusted throughout the deposition process. If not enough silicon precursor is administered, then the etching reaction may dominate and the overall process is slowed down. Also, harmful over etching of substrate features may occur. If not enough etchant precursor is administered, then the deposition reaction may dominate reducing the selectivity to form monocrystalline and polycrystalline materials across the substrate surface. Also, conventional selective epitaxy processes usually require a high reaction temperature, such as about 800° C., 1,000° C. or higher. Such high temperatures are not desirable during a fabrication process due to thermal budget considerations and possible uncontrolled nitridation reactions to the substrate surface.

As an alternative to a conventional selective epitaxy process, previously incorporated U.S. patent application Ser. No. 11/001,774, filed Dec. 1, 2004 (Docket No. 9618) describes an alternating gas supply (AGS) process that includes repeating a cycle of a deposition process and an etching process until the desired thickness of an epitaxial layer is formed. Because an AGS process uses separate deposition and etching steps, deposition precursor concentrations need not be maintained during etching steps and etching precursor concentrations need not be maintained during deposition steps. In some cases, lower reaction temperatures may be employed.

For both selective epitaxy and AGS processes, a need remains for apparatus for efficiently practicing such processes.

### SUMMARY OF THE INVENTION

In some aspects of the invention, a first method of epitaxial film formation is provided that includes pre-cleaning a substrate in a first processing chamber utilizing a first gas prior to epitaxial film formation, transferring the substrate from the first processing chamber to a second processing chamber through a transfer chamber under a vacuum, and forming an epitaxial layer on the substrate in the second processing chamber without utilizing the first gas.

In further aspects of the invention, a second method of epitaxial film formation is provided that includes pre-cleaning a substrate in a first processing chamber utilizing hydrogen gas prior to epitaxial film formation, transferring the substrate from the first processing chamber to a second processing chamber through a transfer chamber under a vacuum, and forming an epitaxial layer on the substrate in the second processing chamber utilizing a carrier gas other than hydrogen.

In yet further aspects of the invention, a third method of epitaxial film formation is provided that includes pre-cleaning a substrate in a first processing chamber utilizing Cl₂ prior to epitaxial film formation, transferring the substrate from the first processing chamber to a second processing chamber through a transfer chamber under a vacuum, and forming an epitaxial layer on the substrate in the second processing chamber utilizing a hydrogen carrier gas.

In some other aspects of the invention, a first cluster tool for use in epitaxial film formation is provided. The first cluster tool includes a first processing chamber adapted to clean a substrate utilizing a first gas prior to epitaxial film formation, a second processing chamber adapted to form an epitaxial layer on the substrate without utilizing the first gas, and a transfer chamber coupled to the first and second processing chambers and adapted to transfer a substrate between the first processing chamber and the second processing chamber while maintaining a vacuum throughout the cluster tool.

In other aspects of the invention, a second cluster tool for use in epitaxial film formation is provided. The second cluster tool includes a first processing chamber adapted to clean a substrate utilizing hydrogen prior to epitaxial film formation, a second processing chamber adapted to form an epitaxial layer on the substrate utilizing a carrier gas other than hydrogen, and a transfer chamber coupled to the first and second processing chambers and adapted to transfer a substrate between the first processing chamber and the second processing chamber while maintaining a vacuum throughout the cluster tool.

In yet other aspects of the invention, a third cluster tool for use in epitaxial film formation is provided. The third cluster tool includes a first processing chamber adapted to clean a substrate utilizing Cl₂ prior to epitaxial film formation, a second processing chamber adapted to form an epitaxial layer on the substrate utilizing a hydrogen carrier gas, and a transfer chamber coupled to the first and second processing chambers and adapted to transfer a substrate between the first processing chamber and the second processing chamber while maintaining a vacuum throughout the cluster tool.

Other features and aspects of the present invention will become more fully apparent from the following detailed description, the appended claims and the accompanying drawings.

### BRIEF DESCRIPTION OF THE DRAWINGS

FIG. 1 is a top plan view depicting an example cluster tool according to embodiments of the present invention.

FIG. 2 illustrates a flowchart depicting a first example method of epitaxial film formation in accordance with embodiments of the present invention.

FIG. 3 illustrates a flowchart depicting a second example method of epitaxial film formation in accordance with embodiments of the present invention.

FIG. 4 illustrates a flowchart depicting a third example method of epitaxial film formation in accordance with embodiments of the present invention.

### DETAILED DESCRIPTION

The introduction of carbon into silicon epitaxial films may produce beneficial electrical properties such as improving the electrical characteristics of the channel of a metal oxide semiconductor field effect transistor (MOSFET). However, such beneficial electrical properties generally are achieved when carbon is substitutionally, rather than interstitially, incorporated within a silicon lattice.

At substrate processing temperatures of about 600 degrees Celsius or less, most carbon atoms are substitutionally incorporated into a silicon lattice during an epitaxial formation process. At higher substrate temperatures, such as about 700 degrees Celsius or more, significant interstitial carbon incorporation may occur. For this reason, it is desirable to employ substrate temperatures below about 700 degrees Celsius, and more preferably substrate temperatures below about 600 degrees Celsius, when forming carbon-containing silicon epitaxial films.

Conventional silicon epitaxial film formation processes employ H2, HCl and a silicon source such as dichlorosilane and are performed at a substrate temperature above about 700 degrees Celsius (e.g., to dissociate HCl and/or the silicon source). One approach to reduce the epitaxial film formation temperature is to employ Cl2 in place of HCl, as Cl2 dissociates efficiently at lower temperatures (e.g., about 600 degrees Celsius or less). Because of incompatibility between hydrogen and Cl2, a carrier gas other than hydrogen, such as nitrogen, may be employed with Cl2. Similarly, a silicon source having a lower dissociation temperature may be employed (e.g., silane, disilane, etc.).

The use of Cl2 as the etchant gas for a silicon epitaxial film formation process may lead to poor surface morphology of the resultant silicon epitaxial film. While not wishing to be bound by any particular theory, it is believed that Cl2 may overagressively attack a silicon epitaxial film surface, producing pitting or the like. The use of Cl2 has been found to be particularly problematic when the silicon epitaxial film contains carbon.

Previously incorporated U.S. patent application Ser. No. 11/227,974, filed Sep. 14, 2005 and titled “USE OF CL₂ AND/OR HCL DURING SILICON EPITAXIAL FILM FORMATION” provides methods for employing Cl₂ as an etchant gas during a silicon epitaxial film formation process that may improve epitaxial film surface morphology. The methods may be used, for example, with the alternating gas supply (AGS) process described in previously incorporated U.S. patent application Ser. No. 11/001,774, filed Dec. 1, 2004 (Docket No. 9618). In some embodiments, both Cl₂ and HCl are employed during an etch phase of a silicon epitaxial film formation process. The presence of HCl appears to reduce the aggressiveness of the Cl₂, even for reduced substrate temperatures at which little HCl may dissociate (e.g., about 600 degrees Celsius or less). Further, during an AGS process, HCl may be continuously flowed during deposition and etch phases of the process (e.g., to improve surface morphology).

According to at least one aspect of the present invention, a cluster tool is provided that includes a transfer chamber and at least two processing chambers. A first of the processing chambers may be used to clean a substrate prior to epitaxial film formation within a second of the processing chambers. The cluster tool is sealed so as to maintain a vacuum throughout the cluster tool during handling of a substrate. Maintaining a vacuum in the cluster tool may prevent exposure of substrates to contaminants (e.g., O₂, particulate matter, etc.).

In conventional epitaxial film formation systems, a substrate is loaded into an epitaxial deposition chamber and is etched to remove any native silicon dioxide layer or other contaminants from the substrate. Typically hydrogen is employed to remove the native silicon dioxide layer. Thereafter, selective epitaxy is used within the epitaxial deposition chamber to form an epitaxial film on the substrate.

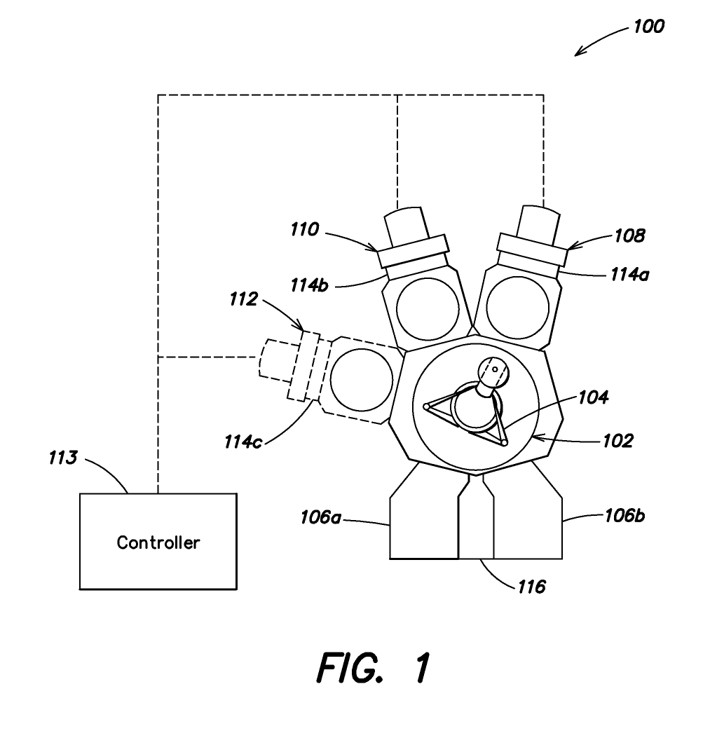

In accordance with the present invention, a separate cleaning chamber is employed to clean a substrate prior to epitaxial film formation. More specifically, a substrate is cleaned within a first processing chamber and transferred (under vacuum) to a second processing chamber for epitaxial film formation. Employing a separate cleaning chamber allows cleaning gases to be used that might be unsuitable for use within an epitaxial film formation chamber. For example, it is conventional to use hydrogen to clean silicon dioxide from a silicon substrate prior to epitaxial film formation. However, as described above, it may be undesirable to use hydrogen during a low temperature epitaxy process that employs Cl₂. Through use of a separate cleaning chamber, a substrate may be cleaned using hydrogen without exposing the epitaxial film formation chamber to hydrogen (or any other undesirable gasses). These and other aspects of the invention are described below with reference to FIGS. 1 to 4.

FIG. 1 is a top plan view of a cluster tool 100 provided in accordance with the present invention. The cluster tool 100 includes a transfer chamber 102 which houses a substrate handler 104. The transfer chamber 102 is coupled to a first loadlock 106a, a second loadlock 106b, a first processing chamber 108, a second processing chamber 110, and, if desired, a third processing chamber 112 (shown in phantom). Fewer or more processing chambers may be employed, and a controller 113 may communicate with and/or control the processes performed within each chamber. One or more of the processing chambers 108, 110, 112 may include (adjacent, attached to, and/or secured within) an ultraviolet apparatus 114a-c (as described below).

Transfer chamber 102 is sealed so as to maintain a vacuum as a substrate is passed by the substrate handler 104 between loadlock chambers 106a-b, processing chambers 108, 110, 112, and transfer chamber 102. Maintaining a vacuum throughout the cluster tool 100 may prevent exposure of the substrate to contaminants (e.g., O₂, particulate matter, etc.).

Loadlock chambers 106a-b may include any conventional loadlock chambers capable of transferring substrates from a factory interface 116 or another source to the transfer chamber 102.

In at least one embodiment of the invention, the first processing chamber 108 is adapted to clean a substrate prior to epitaxial film formation. For example, the first processing chamber 108 may be a conventional preclean chamber that employs any suitable preclean process such as Ar, He, H₂ or N₂ sputtering to remove a native oxide or otherwise clean a surface of a substrate prior to epitaxial film formation. A Cl₂ or other chlorine-based cleaning process also may be used.

The second processing chamber 110 and/or the third processing chamber 112, if employed, may include any suitable epitaxial film formation chamber. An exemplary epitaxial film chamber may be found in the Epi Centura® system and the Poly Gen° system available from Applied Materials, Inc., located in Santa Clara, Calif., although other epitaxial film chambers and/or systems may be used.

Each processing chamber 108, 110 and 112 is coupled to an appropriate gas supply for receiving any gasses required during epitaxial film formation. For example, the first processing chamber 108 may be coupled to a source of hydrogen, and receive hydrogen during any precleaning process performed within the first processing chamber 108. Similarly, the second and/or third processing chambers 110, 112 may be coupled to sources of a carrier gas (e.g., hydrogen, nitrogen, etc.), etchant gases (e.g., HCl, Cl₂, etc.), silicon sources (e.g., silane, disilane, etc.), carbon sources, germanium sources, other dopant sources, etc.

In some embodiments of the present invention, the first processing chamber 108 is adapted to employ hydrogen to preclean a substrate prior to epitaxial film formation within the second processing chamber 110. The second processing chamber 110 is adapted to use a carrier gas other than hydrogen, such as nitrogen during epitaxial film formation on the substrate. For example, the second processing chamber 110 may employ a nitrogen carrier gas with Cl₂ and/or HCl and an appropriate silicon source to form an epitaxial layer on the substrate (e.g., via an AGS or other epitaxial process as described in previously incorporated U.S. patent application Ser. No. 11/227,974, filed Sep. 14, 2005 (Docket No. 9618/P1)). Carbon, germanium and/or other dopants also may be employed. A similar or other epitaxial process may be performed within the third processing chamber 112 if desired.

Employing a separate cleaning chamber (first processing chamber 108) allows cleaning gases to be used that might be unsuitable for use within the epitaxial film formation chamber(s) (second and/or third processing chambers 110, 112). In the example above, when Cl₂ is employed as an etchant during epitaxial film formation within the second processing chamber 110, it is undesirable to have hydrogen present within the second processing chamber 110 (e.g., due to incompatibility between hydrogen and Cl₂). Accordingly, use of a separate preclean chamber, such as the first processing chamber 108, allows a substrate to be cleaned using hydrogen without introducing hydrogen to the processing chamber used for epitaxial film formation.

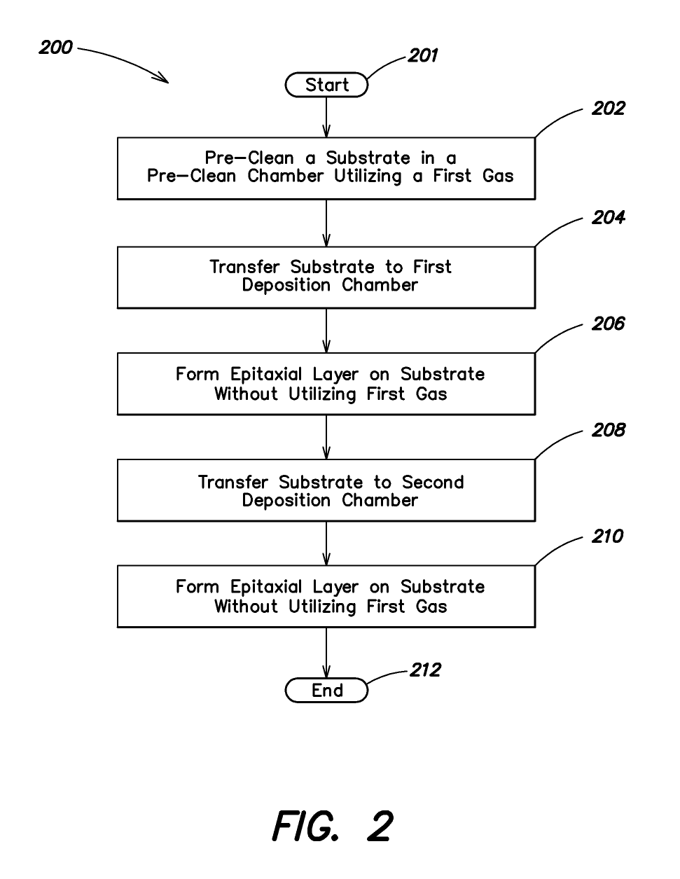

As another alternative, the first processing chamber 108 may be used to preclean a substrate using a Cl₂ process, such as via the use of Cl₂ and/or HCl with a nitrogen carrier gas (e.g., the same etch chemistry used during a low temperature AGS epitaxial film formation process as described in previously incorporated U.S. patent application Ser. No. 11/227,974, filed Sep. 14, 2005 (Docket No. 9618/P1)). Thereafter, a conventional selective epitaxy process using a hydrogen carrier gas may be used to form an epitaxial layer on the substrate within the second and/or third processing chamber 110, 112. Examples of these and other methods are described below with reference to FIGS. 2-4.

FIG. 2 illustrates a flowchart of a first method 200 of epitaxial film formation in accordance with the present invention.

The method 200 begins with step 201. In step 202, a substrate may be pre-cleaned in a pre-clean chamber (e.g., first processing chamber 108) prior to epitaxial film formation. The pre-cleaning process may utilize a first gas (e.g., hydrogen, nitrogen, chlorine, etc.).

In step 204, the substrate may be transferred (e.g., by the substrate handler 104) from the pre-clean chamber to a deposition chamber (e.g., second processing chamber 110). For example, this transfer may occur through the transfer chamber 102 which is maintained at a vacuum.

Following the transfer of the substrate (step 204), an epitaxial layer may be formed on the substrate in the deposition chamber in step 206. The epitaxial layer may be formed on the substrate without utilizing the first gas used in the pre-cleaning chamber in step 202. Exemplary gasses which may be used (provided they have not been previously used in step 204) include nitrogen, hydrogen, helium, argon, etc., as a carrier gas, HCl, Cl₂, a combination of the same, etc., as etchant gasses, silane, disilane, etc., as a silicon source, and various other gasses such as a germanium source, a carbon source or other dopant sources.

If required, any Cl-containing or other species in the pre-clean or deposition chamber may be activated (e.g., by ultraviolet apparatus 114b).

After deposition of an epitaxial layer in step 206, the substrate may be transferred (by the substrate handler 104) to a second deposition chamber (e.g., third processing chamber 112) in step 208. The substrate is transferred (through transfer chamber 102) under a vacuum.

In step 210, an additional epitaxial layer may be formed on the substrate in the second deposition chamber using an appropriate carrier gas, etchant gas, silicon source, dopant source, etc.

Any Cl-containing or other species in the second deposition chamber (e.g., third processing chamber 112) may be activated (e.g., by ultraviolet apparatus 114c). The method 200 ends in step 212.

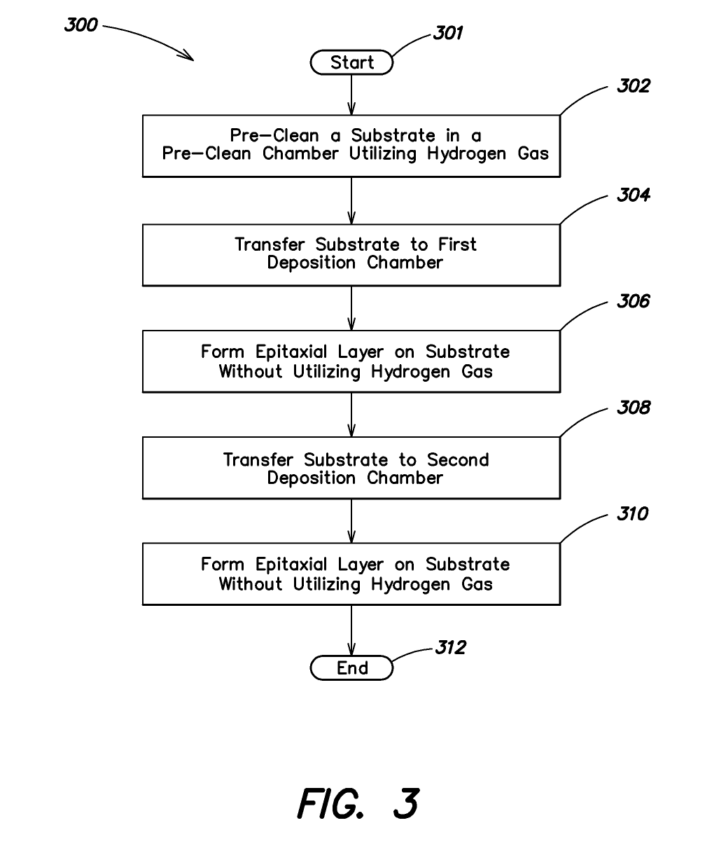

FIG. 3 illustrates a flowchart of a second method 300 of epitaxial film formation in accordance with the present invention.

The method 300 begins with step 301. In step 302, a substrate may be pre-cleaned in a pre-clean chamber (e.g., first processing chamber 108) prior to epitaxial film formation. The pre-cleaning process may utilize hydrogen gas to remove any silicon dioxide layer from the substrate using a conventional hydrogen process.

In step 304, the substrate is transferred (by the substrate handler 104) from the pre-clean chamber to a deposition chamber (e.g., second processing chamber 110). This transfer occurs (through the transfer chamber 102) under a vacuum.

Following the transfer of the substrate (step 304), an epitaxial layer may be formed on the substrate in the deposition chamber in step 306. The epitaxial layer is formed on the substrate without utilizing hydrogen gas as was used in the pre-cleaning chamber (step 302). Exemplary gasses which may be used include nitrogen, helium, or argon carrier gasses, HCl and/or Cl₂ as an etchant gas, silane, disilane, etc., as a silicon source, and various other gasses such as a germanium source, a carbon source or other dopant sources.

If required, any Cl-containing species in the deposition chamber (e.g., second processing chamber 110) may be activated, such as by ultraviolet apparatus 114b.

After deposition of an epitaxial layer in step 306, the substrate may be transferred (by the substrate handler 104) to a second deposition chamber (e.g., third processing chamber 112) in step 308. The substrate is transferred (through transfer chamber 102) under a vacuum.

In step 310, an additional epitaxial layer may be formed on the substrate in the second deposition chamber using an appropriate carrier gas, etchant gas, silicon source, dopant source, etc. The epitaxial layer may be formed with, but preferably without, hydrogen.

Any Cl-containing or other species in the second deposition chamber (e.g., third processing chamber 112) may be activated, such as by ultraviolet apparatus 114c. The method 300 ends at step 312.

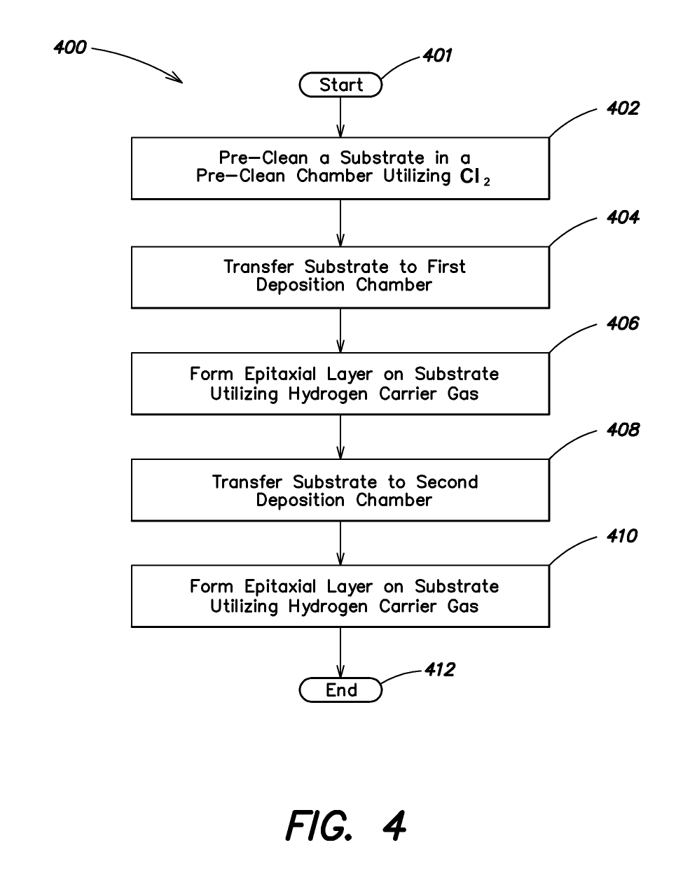

FIG. 4 illustrates a flowchart of a third method 400 of epitaxial film formation in accordance with the present invention.

The method 400 begins with step 401. In step 402, a substrate may be pre-cleaned in a pre-clean chamber (e.g., first processing chamber 108) prior to epitaxial film formation. The pre-cleaning process may utilize Cl₂ (as a cleaning gas). For example, Cl₂ with or without HCl may be used with a nitrogen carrier gas to etch silicon dioxide or other contaminants from the substrate. Exemplary Cl₂ etch processes are described in U.S. patent application Ser. No. 11/047,323, filed Jan. 28, 2005 (Docket 9793) which is hereby incorporated by reference herein in its entirety. For example, a carrier gas and Cl₂, with or without a silicon source, may be used to etch a silicon-containing surface using a substrate temperature in the range of about 500 to 700 degrees Celsius. If desired, the ultra-violet apparatus 114a may be used to activate any Cl-containing or other species required for cleaning the substrate (e.g., to allow lower C1 flow rates and/or lower temperatures).

In step 404, the substrate is transferred such as by the substrate handler 104 from the pre-clean chamber to a deposition chamber (e.g., second processing chamber 110). This transfer occurs (through the transfer chamber 102) under a vacuum.

Following the transfer of the substrate (step 404), an epitaxial layer may be formed on the substrate in the deposition chamber in step 406. The epitaxial layer may be formed on the substrate utilizing any suitable epitaxy formation method such as AGS or conventional selective epitaxy using a hydrogen carrier gas.

After deposition of an epitaxial layer in step 406, the substrate may be transferred such as by the substrate handler 104 to a second deposition chamber (e.g., third processing chamber 112) in step 408. The substrate is transferred (through transfer chamber 102) under a vacuum.

In step 410, an epitaxial layer may be formed on the substrate in the second deposition chamber. The epitaxial layer may be formed on the substrate utilizing any appropriate epitaxy formation method.

The method ends at step 412.

The foregoing description discloses only exemplary embodiments of the invention. Modifications of the above disclosed apparatus and methods which fall within the scope of the invention will be readily apparent to those of ordinary skill in the art. For instance, while the cleaning and epitaxial formation processes described herein have been primarily hydrogen and Cl₂ processes, it will be understood that other gases may be used in the first, second, and/or third processing chambers 108, 110, 112.

Accordingly, while the present invention has been disclosed in connection with exemplary embodiments thereof, it should be understood that other embodiments may fall within the spirit and scope of the invention, as defined by the following claims.

The invention claimed is:

1. A method of epitaxial film formation comprising:
prior to epitaxial film formation, pre-cleaning a substrate in a first processing chamber utilizing a first gas;
transferring the substrate from the first processing chamber to a second processing chamber through a transfer chamber under a vacuum; and
forming an epitaxial layer on the substrate in the second processing chamber without utilizing the first gas.

2. The method of claim 1 further comprising
transferring the substrate from the second processing chamber to a third processing chamber through the transfer chamber while maintaining a vacuum; and
forming an epitaxial layer on the substrate in the third processing chamber without utilizing the first gas.

3. The method of claim 1 wherein the first gas is hydrogen and wherein forming an epitaxial layer on the substrate comprises utilizing a nitrogen carrier gas.

4. The method of claim 1 wherein the first gas is nitrogen and wherein forming an epitaxial layer on the substrate comprises utilizing hydrogen.

5. The method of claim 1 wherein the first gas is hydrogen and wherein forming an epitaxial layer on the substrate comprises utilizing helium.

6. The method of claim 1 wherein the first gas is hydrogen and wherein forming an epitaxial layer on the substrate comprises utilizing argon.

7. The method of claim 1 further comprising:
activating a reactive species in the second processing chamber with an ultraviolet apparatus.

8. A method of epitaxial film formation comprising:
pre-cleaning a substrate in a first processing chamber utilizing hydrogen gas prior to epitaxial film formation;
transferring the substrate from the first processing chamber to a second processing chamber through a transfer chamber under a vacuum; and
forming an epitaxial layer on the substrate in the second processing chamber utilizing a carrier gas other than hydrogen.

9. The method of claim 8 further comprising:
transferring the substrate from the second processing chamber to a third processing chamber through the transfer chamber while maintaining a vacuum; and
forming an epitaxial layer on the substrate in the third processing chamber utilizing a carrier gas other than hydrogen.

10. The method of claim 8 further comprising:
activating a reactive species in the second processing chamber with an ultraviolet apparatus.

11. The method of claim 8 further comprising:
employing the hydrogen gas to remove at least one silicon dioxide layer from the substrate.

12. The method of claim 8 further comprising:
utilizing one of nitrogen, helium or argon as carrier gases and Cl₂ as an etchant gas in the formation of the epitaxial layer.

13. The method of claim 12 wherein hydrogen is incompatible with Cl₂ for an epitaxial formation process at a temperature below 700 degrees Celsius.

14. A method of epitaxial film formation comprising:
pre-cleaning a substrate in a first processing chamber utilizing Cl₂ prior to epitaxial film formation;
transferring the substrate from the first processing chamber to a second processing chamber through a transfer chamber under a vacuum; and
forming an epitaxial layer on the substrate in the second processing chamber utilizing a hydrogen carrier gas.

15. The method of claim 14 further comprising:
transferring the substrate from the second processing chamber to a third processing chamber through the transfer chamber while maintaining a vacuum; and
forming an epitaxial layer on the substrate in the third processing chamber utilizing the hydrogen carrier gas.

16. The method of claim 14 further comprising:
activating a reactive species in the first processing chamber with an ultraviolet apparatus.

17. The method of claim 14 further comprising:
etching contaminants from the substrate with Cl₂.

18. The method of claim 14 further comprising:
etching silicon dioxide from the substrate with Cl₂.

19. The method of claim 14 further comprising:
employing a substrate temperature of about 500 to 700 degrees Celsius in the first processing chamber.

20. The method of claim 14 further comprising:
utilizing HCl in the first processing chamber with the Cl₂ to pre-clean the substrate in a first processing chamber prior to epitaxial film formation.
